(19) United States
(12) Patent Application Publication
(10) Pub. No.: US 2024/0329127 A1
(43) Pub. Date: Oct. 3, 2024

(54) PIN FAULT DETECTION SYSTEM

(71) Applicant: Texas Instruments Incorporated, Dallas, TX (US)

(72) Inventors: David Megaw, Gilbert, AZ (US); Daniel Tennant, Phoenix, AZ (US)

(21) Appl. No.: 18/193,308

(22) Filed: Mar. 30, 2023

(51) Int. Cl. G01R 31/28

(52) U.S. Cl. CPC G01R 31/2896

(57) ABSTRACT

A pin-checking system configured to check for one or more fault types across any number of pins (any terminal). A pin fault detector circuit may be coupled to a given terminal to check for each of the fault types on the terminal. In an example, the pin fault detector includes a first voltage regulator and a second voltage regulator each coupled to the given terminal, and at least one fault comparison block for each fault type configured to receive a test current from the first voltage regulator and/or the second voltage regulator, determine if a given fault type is present on the terminal based on the received test current, and generate an appropriate fault signal. The fault signal may be provided, for example, to a fault response block, which may include any number of pre-determined fault responses to execute based on which terminals exhibit which fault types.

### TECHNICAL FIELD

This description relates to integrated circuits, and more particularly, to detecting various pin faults of a given integrated circuit.

### BACKGROUND

Numerous safety considerations are made when designing and testing integrated circuits. One critical safety consideration is a response from a device to various pin faults that can occur in the application. For some applications, such as automotive circuits, certain pin faults can degrade the fault metrics of the device so significantly that even a single pin fault can make the circuit unable to reach the required safety goals to be used in production. Many such integrated circuits can have high pin counts, and the type of fault and how many faults can be tolerated can be a moving target based on the application. Thus, a number of non-trivial issues remain with fault checking the pins of a given integrated circuit.

### SUMMARY

A pin-checking system is described that includes circuitry configured to test any number of pins (including, but not limited to, input/output pins, power pins, and ground pins). Such pins may be referred to herein as I/O pins of an integrated circuit for one or more fault types. The pin-checking system may be embedded within the integrated circuit itself, and in some such cases may perform the fault detection operations when starting up the device, or periodically. The pin-checking system is able to quickly and automatically assess if a fault is present on any predetermined pins and may also provide different fault responses, for example, depending on fault type and which pin(s) exhibit that fault.

According to some embodiments, a fault detection system includes a pull-up driver circuit having an output coupled to a terminal, a pull-down driver circuit having an output coupled to the terminal, and a comparator circuit configured to compare driver current at the terminal to an expected driver current range, and to output a fault signal associated with the terminal responsive to the driver current being out of range.

According to some embodiments, an integrated circuit includes an integrated circuit package having a terminal, and a fault detector circuit within the integrated circuit package and coupled to the terminal. The fault detector circuit is designed to output at least one fault signal associated with the terminal. The fault detector circuit includes a first voltage regulator coupled to the terminal, a second voltage regulator coupled to the terminal, and a fault comparison block configured to receive a mirrored current from the first voltage regulator and/or the second voltage regulator. The fault comparison block is also configured to output a fault signal of the at least one fault signal.

According to some embodiments, an integrated circuit includes a plurality of pins, a multiplexer having inputs coupled to corresponding pins of the plurality of pins, and a pin fault detector having a pin input coupled to an output of the multiplexer and configured to output at least one fault signal associated with one pin of the plurality of pins as selected by the multiplexer. The pin fault detector includes a first voltage regulator coupled to the pin input, a second voltage regulator coupled to the pin input, and at least one fault comparison block configured to receive a mirrored current from the first voltage regulator and/or the second voltage regulator. Each of the one or more fault comparison blocks is configured to output a corresponding fault signal of the at least one fault signal.

### BRIEF DESCRIPTION OF THE DRAWINGS

FIG. 1 is a block diagram of a pin-checking system, in an example.

FIG. 2 is a block diagram showing multiplexing between pins within the pin-checking system, in an example.

FIG. 3 is a block diagram of a pin fault detector within the pin-checking system, in an example.

FIG. 4 is a schematic diagram of the pin fault detector, in an example.

FIG. 5 provides a timing diagram of fault detection between two pins, in an example.

FIG. 6 provides another timing diagram of fault detection along with applied signal voltages between two pins, in an example.

FIG. 7 is a schematic diagram of a fault response circuit, in an example.

FIGS. 8A-8D are schematic diagrams of fault response circuits each configured to provide a corresponding fault response, in some examples.

### DETAILED DESCRIPTION

A pin-checking system is described. The system may be configured to check for various fault types across any number of pins, and output any number of pre-determined fault responses depending on what faults were found. Example types of pin faults that may be detected include a grounded pin fault, a floating pin fault, a shorted-to-supply pin fault, or a shorted-to-an-adjacent pin fault. A pin fault detector circuit may be coupled to a given pin to check for each of the fault types on the pin. Multiple pins may be multiplexed with a corresponding pin fault detector. In an example, the pin fault detector includes a first voltage regulator and a second voltage regulator each coupled to the given pin and at least one fault comparison block for each fault type designed to receive a test current from the first voltage regulator and/or the second voltage regulator. The fault comparison block determines if a given fault type is present on the pin based on the received test current and outputs a fault signal to a fault response block. The fault response block may include any number of fault response circuits that receive fault signals from the at least one fault comparison block. The fault response block may also include any number of pre-determined fault responses to execute based on which pins exhibit which fault types. The fault responses and the criteria for executing the fault responses may be hardwired into the fault response circuits or dynamically configurable. As will be appreciated, the term “pin” as used herein is not intended to be limited to pins only; rather, the use of “pin” may also refer to, for example, a pad (such as the pad of an integrated circuit package that is bump-soldered to a printed circuit board), a lead, a wire bond, a terminal (internal or external to a given integrated circuit package), or other such interconnection to an integrated circuit that might be susceptible to a detectable fault as variously described herein.

### General Overview

As described above, a number of non-trivial issues are associated with fault checking any pins of an integrated circuit. Certain devices have high safety standards where even a single pin fault of a certain type on a certain pin can make the device unsafe for use. One example of such a device is a buck converter (e.g., a DC-DC voltage regulator) used in automotive or other transportation applications. For devices with low pin counts, the pin operation can be modified to be tolerant of faults and to fail safely and the pin order can be rearranged to avoid unsafe adjacent pin shorts. But such approaches are not always viable with devices having high pin counts (e.g., hundreds or thousands of pins) as they can add significant design complexity and cost and may degrade performance due to non-optimal pinout. Furthermore, manually checking for pin faults on each device during the fabrication process is labor intensive and may not provide an accurate picture of what faults are considered unsafe based on the application for the given device.

Thus, a pin-checking system is described herein. In an example, the system may be integrated within a given device to be fault tested. The pin-checking system may include any number of pin fault detector circuits that are used to check any number of terminals (e.g., I/O pins, pads, wire bonds) on the device, such as during startup or periodically, to detect the presence of pin faults, and may allow easy configuration of the fault response for a number of pin/fault combinations. In an example, each pin fault detector circuit includes a pullup servo voltage driver and a pulldown servo voltage driver to regulate the pin voltage and measure the resulting pin current. According to some such embodiments, the pin current is mirrored and compared to various reference current values to determine if the pin is, for example, grounded or shorted to a voltage supply. According to some such embodiments, the pin current from both servo voltage drivers along with a measure of the capacitance of the pin may be used together to determine if the pin has a floating voltage. According to some such embodiments, the pin current measured across adjacent time frames for a given pin while driving conditions for an adjacent pin change across the adjacent time frames may be used to determine if the pin is shorted to its adjacent pin. Any number of other fault types may also be detected based on the pin current generated by the pullup servo voltage driver and/or the pulldown servo voltage driver. A controller may be used to bias the servos and/or to control timing of the pin fault determinations and capturing of pin faults.

In some embodiments, the various pin faults detected by the pin fault detector circuit(s) are passed on to a fault response block that includes logic for selecting one or more fault responses based on what faults were found on what pins. For example, if a given pin is shown to have a particular fault (e.g., shorted to ground) this may be a catastrophic situation that results in a fault response configured to shut down the operation of the device, or to switch-in a redundant circuit to replace the faulty circuit. In another example, if a given pin is shown to have a less critical fault (e.g., floating pin) that is not serious enough to stop operation of the device, a different fault response may be generated that provides an appropriate warning without ceasing the operation of the device. Numerous other variations would be apparent based on the embodiments described herein.

### Electronic System

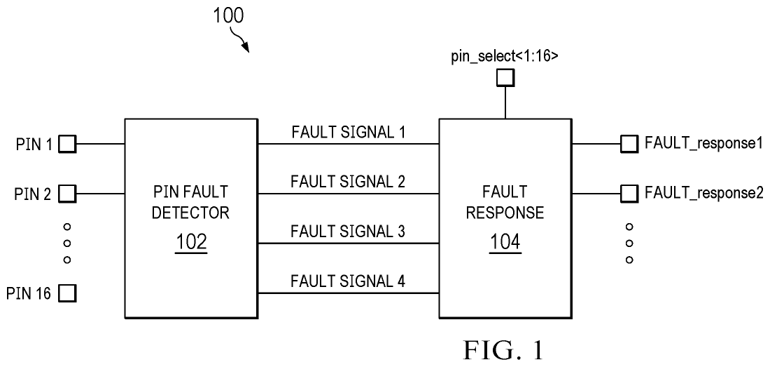

FIG. 1 illustrates at least a portion of an example fault detection system 100, according to some embodiments. Fault detection system may be integrated within an integrated circuit chip package (e.g., with pins or pads for its input and output terminals) and/or on the same substrate as another integrated circuit for testing the pins associated with the chip package and/or the integrated circuit. The various pins to be tested may be referred to as pins or terminals, although the pins or terminals may be used for any purpose and need not be limited to input/output purposes. Any number of faults can be detected across any number of pins using fault detection system 100. In some embodiments, fault detection system 100 is integrated with a switching regulator, such as a buck converter, to test for any faults on various pins or terminals of the regulator.

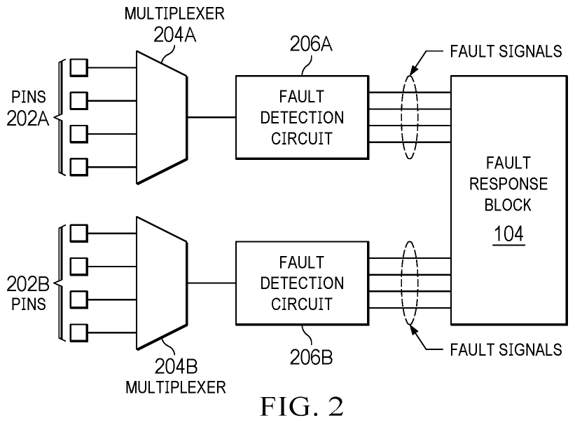

According to some embodiments, a fault detector block 102 is coupled to one or more pins for testing for faults on the one or more pins. Fault detector block 102 may include any number of fault detection circuits designed to test a given pin for any number of pre-determined faults. In some examples, each pin is coupled to a dedicated fault detection circuit, while in other examples, any number of pins may be selectively coupled to a given fault detection circuit using a multiplexer or similar switching element, as discussed in more detail with reference to FIG. 2. Although 16 pins are used in this example, fault detector block 102 can be configured to detect faults on any number of pins.

According to some embodiments, fault detector block 102 is designed to generate any number of fault signals depending on how many pre-determined fault types are desired. In the illustrated example, four fault signals may be generated for each pin. According to some embodiments, the four fault signals may represent a grounded terminal fault, a floating terminal fault, a shorted to supply terminal fault, and a shorted to adjacent terminal fault. The grounded terminal fault may represent a pin that has been shorted to ground. The floating terminal fault may represent a pin having a floating voltage that is not connected to the rest of the circuit. The shorted to supply terminal fault may represent a pin that has been shorted to a supply rail within the circuit. The shorted to adjacent terminal fault may represent a pin that has been shorted to an adjacent pin of the chip package. Each fault type may be detected for any number of different pins using fault detector block 102.

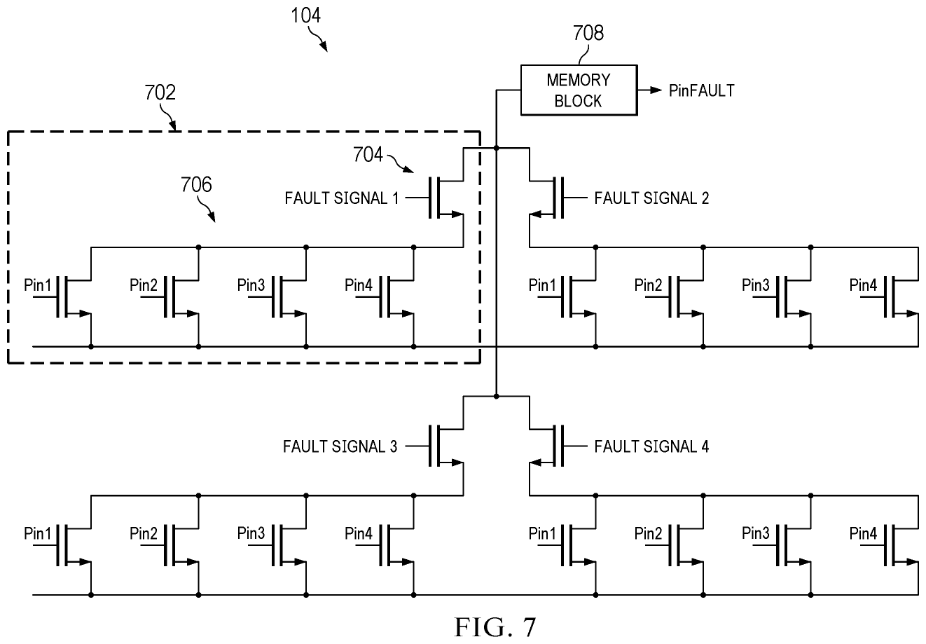

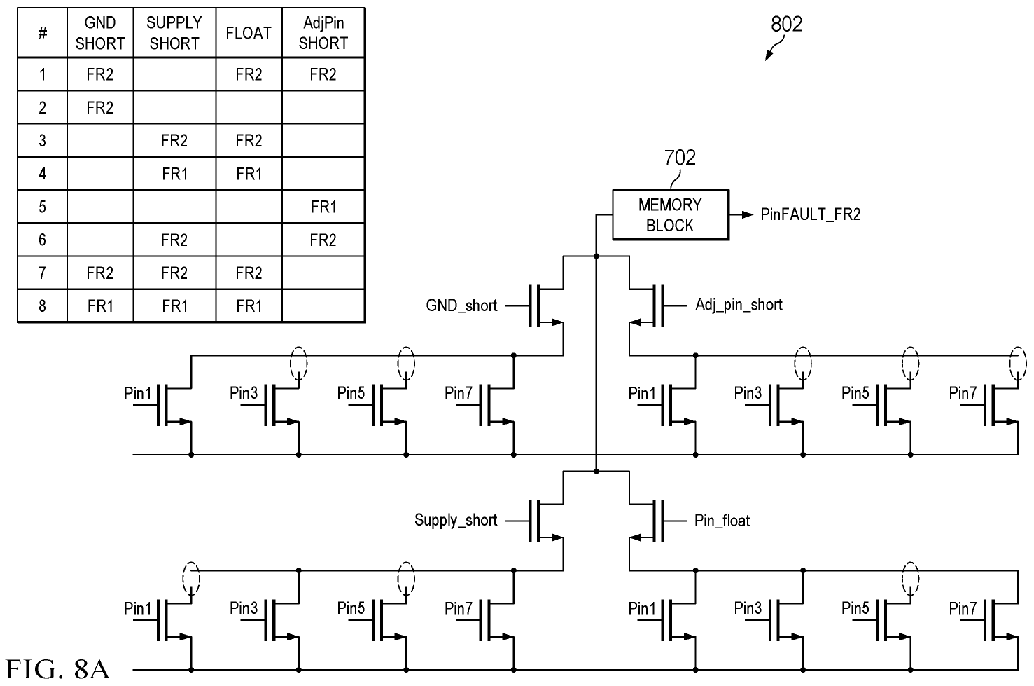

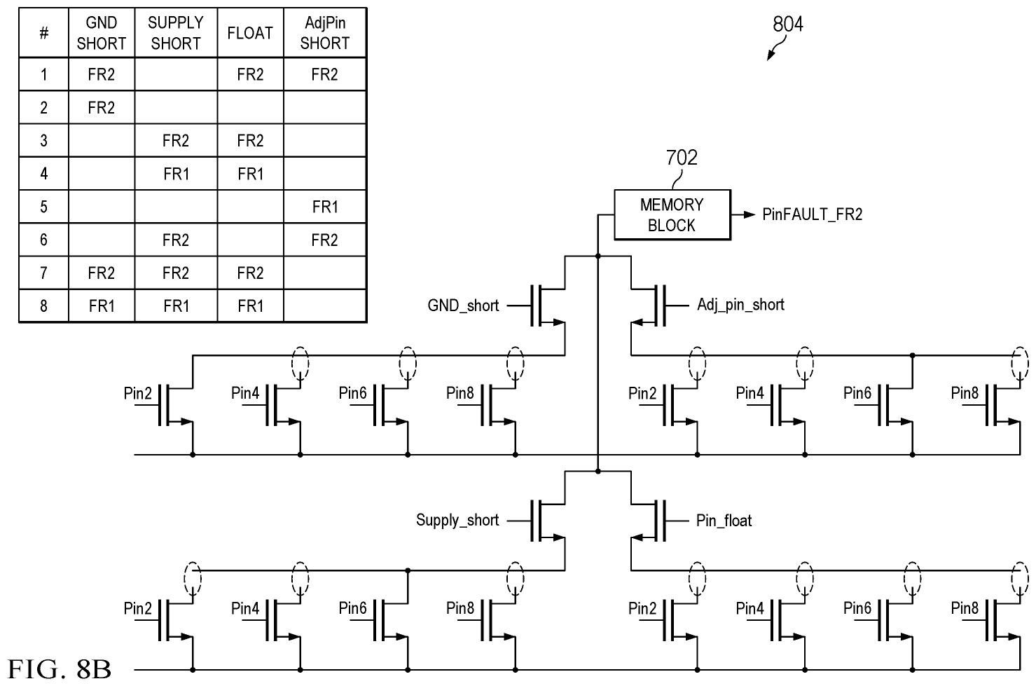

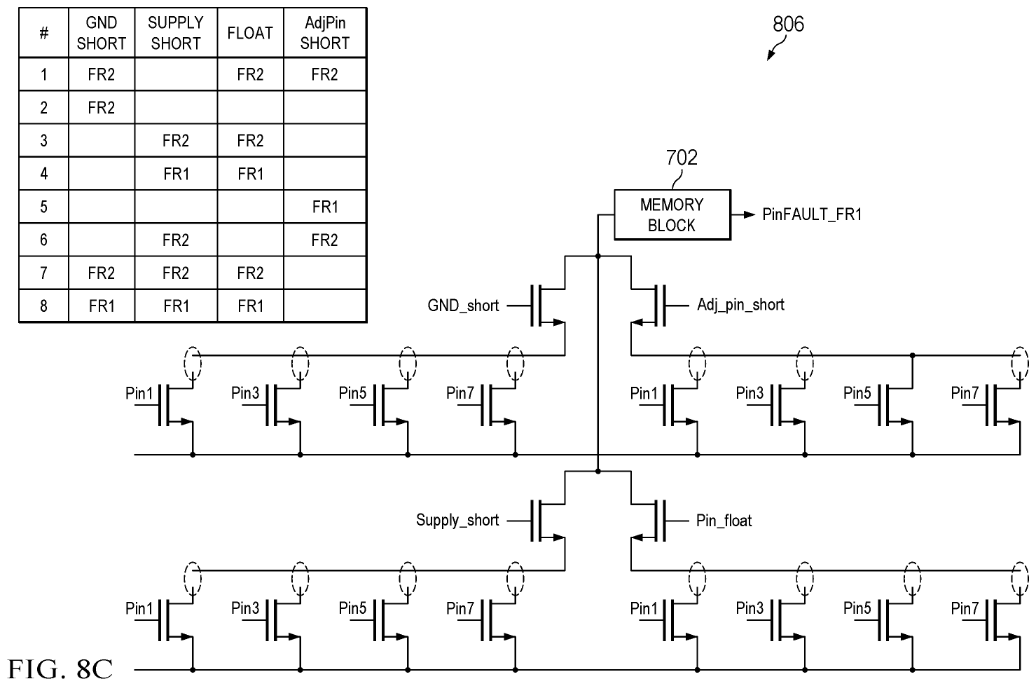

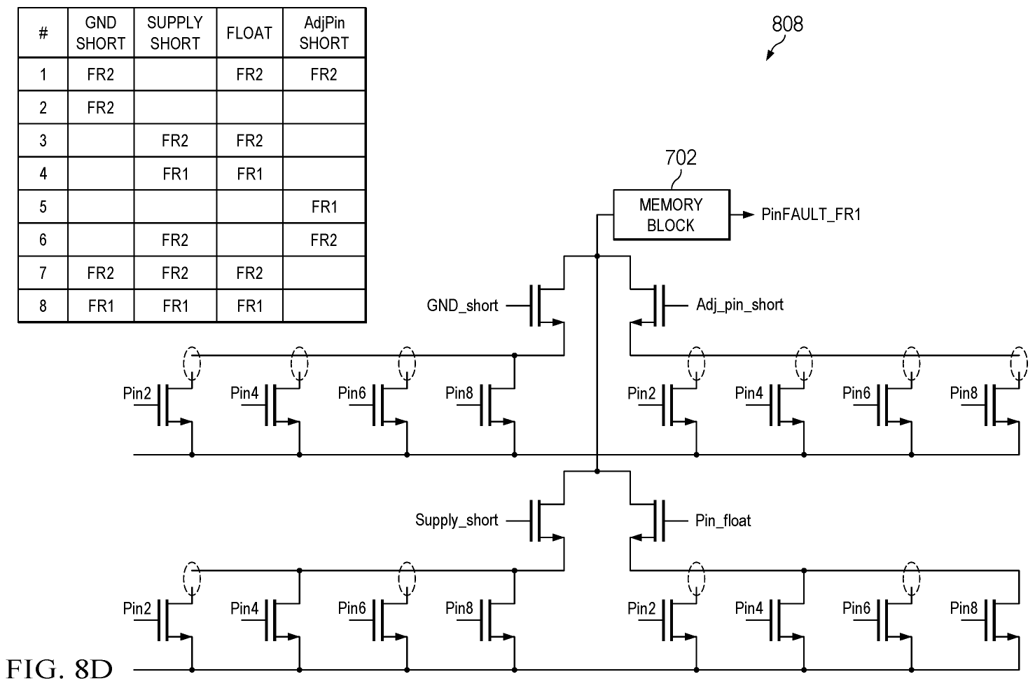

The assertion of a given fault signal for a given pin does not necessarily mean that the pin is working improperly. Indeed, several pins may be designed to be shorted to ground, shorted to a supply, etc. At the same time, it may not be critical what state certain other pins are in, while it is critical that other pins do no exhibit certain fault types. Thus, according to an embodiment, a fault response block 104 is provided to receive the various fault signals generated by fault detector block 102. Fault response block 104 includes suitable switching circuitry to receive the fault signals along with a pin select signal for the number of tested pins and is designed to determine what actions to take based on what faults are asserted on given pins. For example, fault response block 104 may be configured to provide a first fault response (FAULT_response1) and/or a second fault response (FAULT_response2) depending on what pins exhibit what fault types. Any number of fault responses may be generated depending on the application. The fault responses and the criteria for asserting each fault response may be predetermined and hardwired within fault response block 104. In some other examples, such criteria may be dynamically programmable. Further details of fault response block 104, along with an example operation for a given set of pin faults, are provided with reference to FIGS. 7 and 8A-8D.

FIG. 2 illustrates another example of a fault detection system where multiple pins are tested using the same fault detection circuit 206. According to some embodiments, a first group of pins 202A are fed into a first multiplexer 204A that is configured to select one of the first group of pins 202A to be fault tested using fault detection circuit 206A. Similarly, a second group of pins 202B are fed into a second multiplexer 204B that is configured to select one of the second group of pins 202B to be fault tested using fault detection circuit 206B. Multiplexing the signals from the various pins may be useful to reduce the number of fault detection circuits needed to test the pins. Furthermore, according to some embodiments, the ability to simultaneously test across two pins allows for the detection of a pin short between the two tested pins (e.g., a shorted to adjacent terminal fault) as described in more detail herein. According to some embodiments, first group of pins 202A may represent even-numbered pins along the chip package or even-numbered pins in a pin check order while second group of pins 202B may represent odd-numbered pins along the chip package or odd-numbered pins in the pin check order. In this way, any adjacent pin pair can be tested for a potential adjacent terminal short.

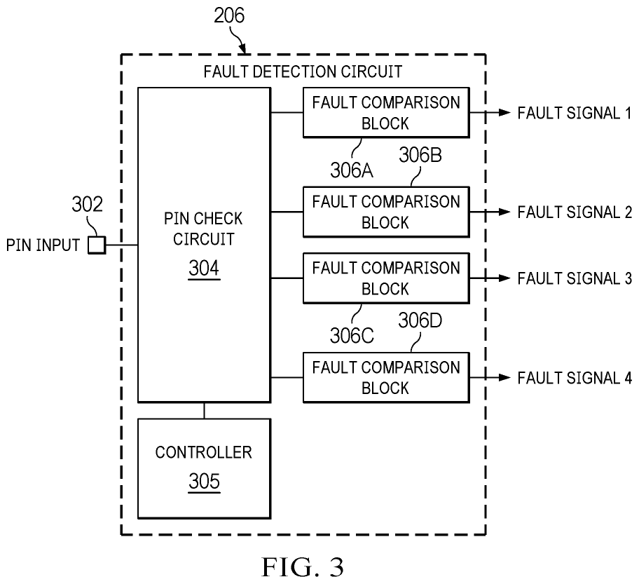

FIG. 3 illustrates a more detailed schematic of a given fault detection circuit 206, according to some embodiments. A given pin input 302 may be directly coupled to a pin check circuit 304 or coupled to pin check circuit 304 via a multiplexer. According to some embodiments, pin check circuit 304 includes driver circuits that are arranged to compare the voltage on pin input 302 to pre-determined reference voltages and generate a pin current (or no pin current) depending on the state of pin input 302. The reference voltages used for the driver circuits may be determined via a controller 305 that changes the reference voltages to predetermined levels over given time periods. The length of the different time periods may also be regulated by controller 305. In some embodiments, controller 305 includes a finite state machine or other similar state machine architecture that changes the voltage level of the reference voltages based on the time period. For example, the different states of the state machine may be configured to select a different tap on a resistive divider of a bandgap reference to select different reference voltages for the drivers within pin check circuit 304. In some embodiments, controller 305 also controls the latching and/or capturing of different pin faults at particular times. The state machine used within controller 305 may be substantially less complex (e.g., only requiring less than five different states) compared to using a state machine that attempts to replace the operation of the entirety of fault detection circuit 206.

According to some embodiments, the pin current generated (or not generated depending on the potential state of pin input 302) is mirrored across various fault comparison blocks 306A-306D to determine if a given fault type is detected. In some examples, each fault comparison block 306A-306D is configured to detect a different fault type from pin input 302. Any number of fault comparison blocks may be used depending on the number of fault types to be detected. In some embodiments, the pin current is mirrored and compared to different current reference sources at one or more of the fault comparison blocks to determine if the corresponding fault signal should be asserted. In some embodiments, the mirrored current may be stored (e.g., using a sample-and-hold scheme) to be compared to another mirrored current from the same pin at a later time to determine if the pin input 302 is from a pin that is shorted to the adjacent pin.

### Circuit Design and Operation

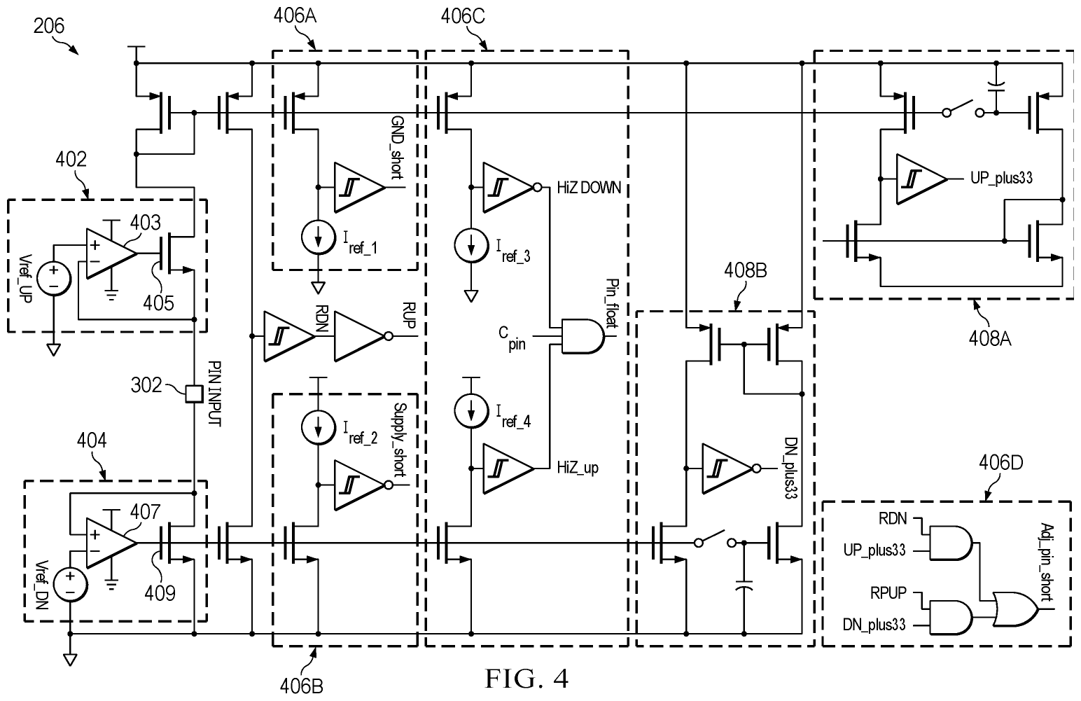

FIG. 4 illustrates a more detailed circuit diagram of fault detection circuit 206, according to some embodiments. The pin check circuit portion includes a pull-up driver 402 coupled to pin input 302 and a pull-down driver 404 coupled to pin input 302. According to some embodiments, pull-up driver 402 is a series voltage regulator while pull-down driver 404 is a shunt voltage regulator. Pull-up driver 402 may be generally any voltage regulator circuit that attempts to pull the voltage of pin input 302 up to the level of a first reference voltage Vref_UP. Similarly, pull-down driver 404 may be generally any voltage regulator circuit that attempts to pull the voltage of pin input 302 down to the level of a second reference voltage Vref_DN. Accordingly, pin input 302 may be coupled to the negative terminal of an operational amplifier within pull-up driver 402 while first reference voltage Vref_UP is coupled to the positive terminal of the operational amplifier within pull-up driver 402, and pin input 302 may be coupled to the positive terminal of an operational amplifier within pull-down driver 404 while second reference voltage Vref_DN is coupled to the negative terminal of the operational amplifier within pull-down driver 404. The values for Vref_UP and Vref_DN are determined by controller 305 as discussed above. According to some embodiments, Vref_DN has a higher voltage than Vref_UP during all time periods to create a dead-band region between Vref_UP and Vref_DN that prevents pull-up driver 402 and pull-down driver 404 from conducting current simultaneously.

In one example, if the voltage on pin input 302 is below the value of Vref_UP, then an operational amplifier 403 of pull-up driver 402 will output a driving voltage that will turn on a coupled field effect transistor (FET) 405 within pull-up driver 402 and conduct a pin current across FET 405 to try to regulate the voltage of pin input 302 up to the value of Vref_UP. Since the voltage on pin input 302 is below the value of Vref_DN, an operational amplifier 407 of pull-down driver 404 will output a driving voltage that will turn off a coupled FET 409 within pull-down driver 404 and no current is generated on pin input 302 from pull-down driver 404.

In another example, if the voltage on pin input 302 is above the value of Vref_DN, then operational amplifier 407 of pull-down driver 404 will output a driving voltage that will turn on FET 409 within pull-down driver 404 and conduct a pin current across FET 409 to try to regulate the voltage of pin input 302 down to the value of Vref_DN. Since the voltage on pin input 302 is above the value of Vref_UP, operational amplifier 403 of pull-up driver 402 will output a driving voltage that will turn off FET 405 within pull-up driver 402 and no current is generated on pin input 302 from pull-up driver 402.

In yet another example, if the voltage on pin input 302 is below the value of Vref_DN and above the value of Vref_UP, then both operational amplifiers 403/407 will output driving voltages that turn off their corresponding FETs 405/409 and no pin current is created.

According to some embodiments, the pin current either sourced or sunk on pin input 302 from pull-up driver 402 or pull-down driver 404, respectively, is mirrored across any number of comparator circuits 406A-406D. Each comparator circuit 406A-406D may be designed to test for a particular fault type. Fault detection circuit 206 may include any number of comparator circuits in order to detect any number of different fault types for a given pin input 302. Comparator circuits 406A-406D may operate in parallel to check for different fault types substantially simultaneously.

In one example, a first comparator circuit 406A may receive mirrored pin current generated by pull-up driver 402 (e.g., the voltage on pin input 302 was below Vref_UP). This mirrored current may be compared to a first reference current I_{ref}_1 using a Schmitt trigger or any other suitable comparator circuit. If the mirrored current is found to be greater than first reference current I_{ref}_1 (or less than first reference current I_{ref}_1 depending on the arrangement of the elements within first comparator circuit 406A), the GND_short fault signal may be asserted to indicate that the voltage on pin input 302 is lower than Vref_UP through a very low impedance, indicating a likely short to ground.

In another example, a second comparator circuit 406B may receive mirrored pin current generated by pull-down driver 404 (e.g., the voltage on pin input 302 was above Vref_DN). This mirrored current may be compared to a second reference current I_{ref}_2 using a Schmitt trigger or any other suitable comparator circuit. If the mirrored current is found to be greater than second reference current I_{ref}_2 (or less than second reference current I_{ref}_2 depending on the arrangement of the elements within second comparator circuit 406B), the Supply_short fault signal may be asserted to indicate that the voltage on pin input 302 is higher than Vref_DN through a very low impedance, indicating a likely short to a supply rail.

In another example, a third comparator circuit 406C may use a third reference current I_{ref}_3 and a fourth reference current I_{ref}_4 to determine that no pin current is being sourced or sunk on pin input 302 (e.g., indicating that the voltage on pin input 302 is between the values of Vref_UP and Vref_DN). Accordingly, third reference current I_{ref}_3 and a fourth reference current I_{ref}_4 may be very small current values to compare with essentially 0 mirrored current and to assert both HiZ_down and HiZ_up signals if the mirrored current is found to be lower than third reference current I_{ref}_3 and fourth reference current I_{ref}_4. Additionally, a capacitance of the tested pin may be measured and, if the measured capacitance is found to be less than a threshold (e.g., a capacitance of 100 pF), Cpin is also asserted. According to some embodiments, the combination of each of HiZ_down, HiZ_up, and Cpin being asserted causes the Pin-float fault signal to be asserted to indicate that the voltage on pin input 302 is floating within a dead-band region (e.g., between the values of Vref_UP and Vref_DN). In some examples, the capacitance is measured and tested against a low threshold to prevent incorrectly asserting the pin-float fault signal on a capacitively loaded pin, which will also conduct no pin current in the dead-band region.

In another example, a fourth comparator circuit 406D may be used to determine if pin input 302 is shorted to an adjacent pin of the chip package. According to some embodiments, fourth comparator circuit 406D utilizes a first sample-and-hold circuit 408A to compare sourced current from pull-up driver 402 across adjacent time periods and a second sample-and-hold circuit 408B to compare sunk current across the adjacent time periods from pull-down driver 404. Briefly, the sourced or sunk pin current for a given pin over a first time period is stored and compared to the sourced or sunk pin current for the given pin over a second time period adjacent to the first time period. Over the same first and second time periods, an adjacent pin has the voltage levels of the pull-up and pull-down drivers change and if such a change affects the compared current from the given pin across the time periods, the pins are determined to be shorted and the Adj_pin_short fault signal is asserted. In some embodiments, the Adj_pin_short fault signal is asserted if the compared current shows a difference greater than a threshold (e.g., at least a 33% shift in current). According to some embodiments, RDN and RUP signals may be used to ensure that signals received from one sample-and-hold circuit 408A/408B do not interfere with the operation of the other sample-and-hold circuit 408A/408B.

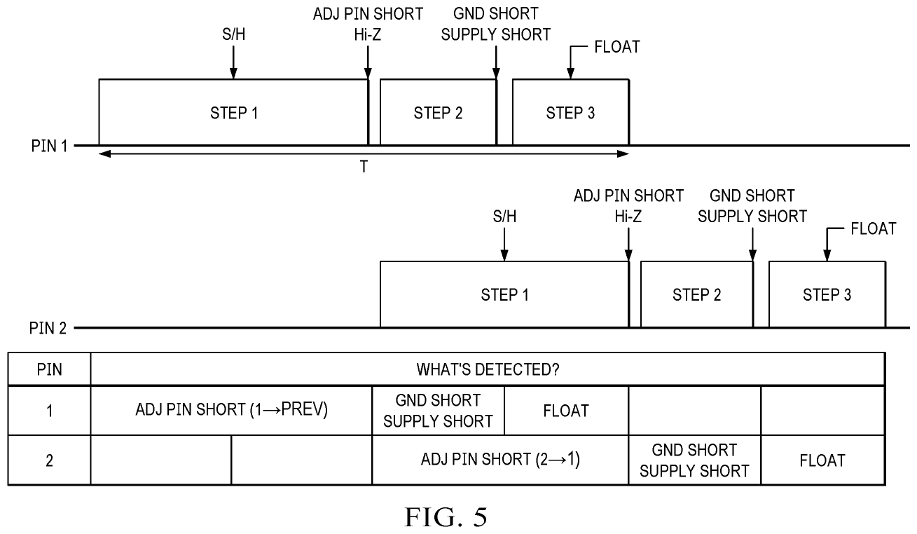

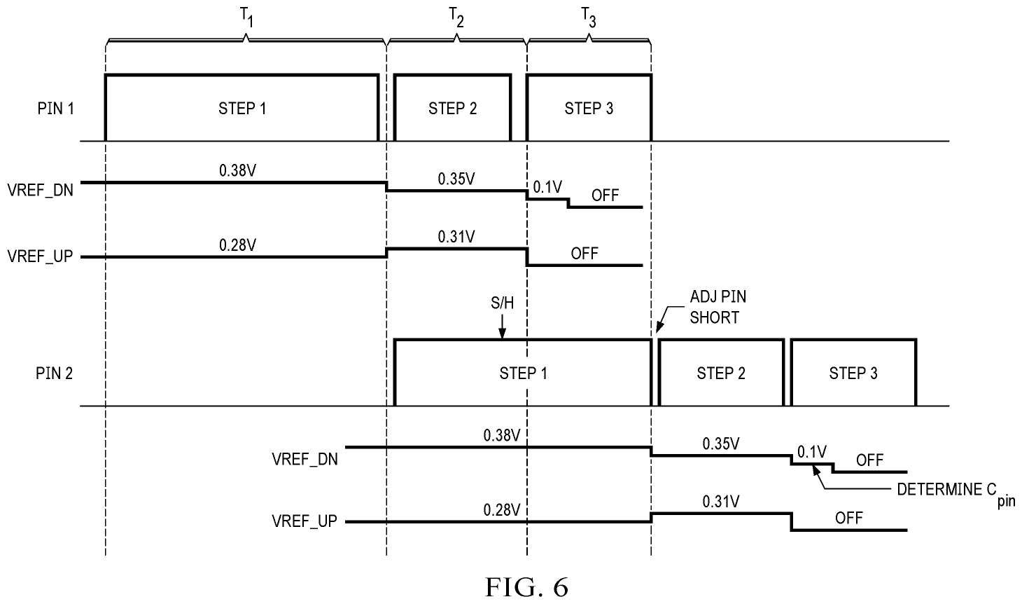

FIG. 5 illustrates an example timing diagram to show the various time steps for two adjacent pins and what is detected along those time steps. Different fault signals are detected at different times depending on the given time step. According to some embodiments, each pin is tested over a total time period T that is made up of three distinct time steps. The time steps may be distinguishable from one another based on the reference voltage levels set for Vref_UP and Vref_DN (as shown in more detail in FIG. 6). The table below the timing diagram and arrows within the timing diagram indicate when certain fault signals are identified. For example, whether or not a given pin is shorted with its previous adjacent pin is determined during a first time step, whether or not the pin is shorted to ground or to a supply rail is determined during a second time step, and whether or not the pin is floating is determined during a third time step. Additionally, the HiZ_down and HiZ_up signals may be asserted during the first time step, although the determination on whether or not the pin is floating is not made until the capacitance can be measured during the third time step. Such step timing and latching of the various signals may be controlled via controller 305.

According to some embodiments, the total pin testing time overlaps for adjacent pins. The overlap allows for adjacent pin shorts to be detected. For example, while pin 2 is being tested in its first time step, pin 1 is being tested across its second and third time steps. The voltages applied to the pull-up and pull-down drivers coupled to pin 2 are different during its first time step compared to the voltages applied to the pull-up and pull-down drivers coupled to pin 1 during its second and third time steps. This is why the sourced or sunk current from pin 2 is stored (S/H) while pin 1 is in its second time step, and when pin 1 changes to its third time step, the stored value can be compared to the new sourced or sunk current on pin 2 during its first time step to determine if an adjacent pin short has occurred.

FIG. 6 illustrates the same timing diagrams from FIG. 5 along with example voltage values for Vref_UP and Vref_DN across each time period for each pin, according to some embodiments. In this example, Vref_DN has a value of 0.38 V during the first time step on either pin, a value of 0.35 V during the second time step on either pin, and changes from a value of 0.1 V to being off during the third time step on either pin. Similarly, Vref_UP has a value of 0.28 V during the first time step on either pin, a value of 0.31 V during the second time step on either pin, and is off during the third time step on either pin. Shared time periods across both pins are identified as a first time period T₁, second time period T₂, and a third time period T₃.

As noted above, the different time steps across the adjacent pin 1 and pin 2 are staggered, but partially overlap. Accordingly, time step 2 of pin 1 occurs during the first half of time step 1 of pin 1 during time period T₂, and time step 3 of pin 1 occurs during the second half of time step 1 of pin 1 during time period T₃, according to some embodiments. The relative lengths of the different time steps may be controlled via controller 305. In some embodiments, the lengths of the time steps may be dynamically or manually adjusted based on the application (e.g., pins with higher capacitance may require longer relative time steps).

Turning to the example shown for Pin 2, during time step 1, the HiZ_down and HiZ_up signals may each be asserted if the voltage on the pin input is between 0.28 V and 0.38 V (e.g., the dead-band region), in which case neither driver will cause any pin current to conduct. Additionally, the pin current, or lack of pin current, is sampled and held (S/H) at the end of time period T₂, and is then compared to the pin current, or lack of pin current, at the end of time period T₃. According to some embodiments, if the pin current from Pin 2 changes from substantially zero pin current during time period T₂ to substantially all of the pin current during time period T₃, then the change in the driver voltages applied to Pin 1 between time periods T₂ and T₃ affected Pin 2, and the pins are determined to be shorted. In such cases, the Adj_pin_short fault signal may be asserted.

Continuing with Pin 2, during time step 2, the voltage on the pin input is compared against the pull-up driver voltage of 0.31 V and the pull-down driver voltage of 0.35 V. If the voltage on the pin input is less than 0.31 V by a wide enough margin (e.g., causing a pin current greater than I_{ref}_1) then the GND_short fault signal may be asserted. If the voltage on the pin input is greater than 0.35 V by a wide enough margin (e.g., causing a pin current greater than I_{ref}_2) then the Supply_short fault signal may be asserted.

During time step 3 on Pin 2, Vref_DN is reduced to 0.1 V temporarily such that any pin voltage that was within the dead-band region will be pulled down to 0.1 V. This will start to discharge the pin voltage with pull-down driver 404 and, if its current settles back to zero within a specified delay, it can be inferred that the pin is floating as it has a capacitance less than a value determined by the slewing limit of pull-down driver 404 and a programmed delay, according to some embodiments. The Cₚᵢₙ signal may be asserted in response to the determination that the current on the pin settled back to zero within the specified delay. This may also prevent incorrectly determining a Pin_float fault is present when pin 302 is driven with an external voltage between Vref_UP and Vref_DN. As noted above, if each of Cpin, HiZ_down, and HiZ_up signals are asserted, then the Pin_float fault signal may be asserted.

It should be understood that the description above for determining pin faults on Pin 2 are performed in the same way for Pin 1 (as seen in the timing diagram). Furthermore, such description could be used to describe the determination of pin faults for any other pin on the package. Due to the overlapping time periods, pin 1 may be coupled to a first fault detection circuit 206A while pin 2 is coupled to a second fault detection circuit 206B.

When various pin fault signals are asserted for one or more pins, a determination is made regarding what actions to take based on what faults have been found on which pins, according to some embodiments. FIG. 7 illustrates an example of fault response block 104, which receives up to four fault signals across four different pins. According to some embodiments, fault response block 104 includes any number of fault response circuits 702 for each fault type. A given fault response circuit 702 may include a fault switch 704 (e.g., a FET) having its gate or switching input coupled to the fault signal received from fault detection circuit 206, and a switch array 706 (e.g., FETs) coupled to a terminal (e.g., source terminal) of fault switch 704, with each of the switches within switch array 706 having its gate or switching input associated with a given pin select signal of a given pin indicating that pin is presently being checked. In the illustrated example, pins 1-4 control the gates of the switches within switch array 706 for each of four different fault signals. For any given fault signal, controlling or pre-determining which pins remain coupled to the associated fault switch 704 is used to assert a PinFAULT response signal if any of the pre-determined pins exhibit the given fault. A memory block 708 may include any suitable data storage architecture, such as a latch configured to store fault values from any of the fault signals and assert the PinFAULT response signal if a fault was received from any of the fault types for a given pin.

According to some embodiments, the connections between any of the switches within switch array 706 and fault switch 704 can be physically severed or dynamically disconnected (e.g., by using another switch). By selectively connecting certain pin switches to certain fault types, only those selected pins will cause the associated PinFAULT signal to be asserted if they exhibit the corresponding fault type of their fault response circuit 702. This is illustrated using a specific example in FIGS. 8A-8D.

It should be understood that fault response block 104 can include any number of fault response circuits 702 depending on the number of fault types to test for. Additionally, each fault response circuit 702 may include an array of switches with any number of switches corresponding to any number of pins being tested.

According to some embodiments, a different fault response circuit 104 is used for each desired fault response. Any number of fault responses (corresponding to any number of fault response circuits 104) can be used in a given application. For example, a first fault response may trigger a total shutdown of one or more integrated circuits (such as of the entire buck converter) due to a critical fault failure of one or more predetermined pins. In another example, a second fault response may trigger a warning light to activate to alert the user that something in the device is not working properly, but it is not serious enough to stop the device from functioning. Any other fault responses can also be used. According to some embodiments, a different fault response circuit 104 is used for a first set of pins than for a second set of pins. For example, different fault response circuits 104 may be used for even-numbered pins than for odd-numbered pins in the pin check order.

FIGS. 8A-8D illustrate examples of fault response circuits 104 across eight different pins to illicit two different possible fault responses, according to some embodiments. Fault response circuit 802 in FIG. 8A is configured to read from odd pins 1, 3, 5, and 7 in the pin check order to determine if the pinFAULT_FR2 response should be asserted. Fault response circuit 804 in FIG. 8B is configured to read from even pins 2, 4, 6, and 8 in the pin check order to determine if the pinFAULT_FR2 response should be asserted. Fault response circuit 806 in FIG. 8C is configured to read from odd pins 1, 3, 5, and 7 to determine if the pinFAULT_FR1 response should be asserted. Fault response circuit 808 in FIG. 8D is configured to read from even pins 2, 4, 6, and 8 to determine if the pinFAULT_FR1 response should be asserted. Four different fault types are being tested for each pin, and are related to the same fault types discussed above with reference to FIG. 4. According to some embodiments, the first fault response FR1 may be associated with a major failure resulting in turning off one or more operations of the integrated circuit, while the second fault response FR2 may be associated with a minor malfunction that only alerts the user that something is not working properly (e.g., producing a sound or turning on a light). Other fault responses may be contemplated.

According to some embodiments, different fault responses are pre-determined based on what pins exhibit what fault types. The table in the top-left corner of each FIG. 8A-8D) illustrates an example fault table, where different fault responses are identified for given pins and given fault types. For example, if pin 2 is found to have any of a GND_short fault, a Float fault, or an adjacent pin fault, then fault response FR2 will be asserted. However, if pin 2 is found to only have a supply short fault, then no fault response is provided. The various fault response circuits 802-808 are configured to provide the different fault responses in line with the fault table. According to some embodiments, this is performed by physically severing (e.g., using laser ablation) connections between certain pin switches and their associated fault switches. In this way, only the pins that remain connected can elicit the given fault response. According to some embodiments, different pin switches may be dynamically disconnected to a given fault switch using, for example, other digital switches or mechanical switches.

Turning to the odd pins in fault response circuit 802 in FIG. 8A, the dashed ovals indicate areas where connections have been severed between certain pin switches and their related fault switch. Accordingly, for the GND_short fault, only odd pins 1 and 7 provide the fault response FR2; for the Adj_pin_short fault, only odd pin 1 provides the fault response FR2; for the Supply_short fault, only odd pins 3 and 7 provide the fault response FR2; and, for the Pin float fault, only odd pins 1, 3, and 7 provide the fault response FR2. Turning to the even pins in fault response circuit 804 in FIG. 8B, the dashed ovals again indicate areas where connections have been severed between certain pin switches and their related fault switch. Accordingly, for the GND_short fault, only even pin 2 provides the fault response FR2; for the Adj_pin_short fault, only even pin 6 provides the fault response FR2; for the Supply_short fault, only even pin 6 provides the fault response FR2; and, for the Pin float fault, none of the even pins provide the fault response FR2. Turning to the odd pins in fault response circuit 806 in FIG. 8C, the dashed ovals again indicate areas where connections have been severed between certain pin switches and their related fault switch. Accordingly, for the GND_short fault, none of the odd pins provide the fault response FR1; for the Adj_pin_short fault, only odd pin 5 provides the fault response FR1; for the Supply_short fault, none of the odd pins provide the fault response FR1; and, for the Pin float fault, none of the odd pins provide the fault response FR1. Turning to the even pins in fault response circuit 808 in FIG. 8D, the dashed ovals again indicate areas where connections have been severed between certain pin switches and their related fault switch. Accordingly, for the GND_short fault, only even pin 8 provides the fault response FR1; for the Adj_pin_short fault, none of the even pins provide the fault response FR1; for the Supply_short fault, only even pins 4 and 8 provide the fault response FR1; and, for the Pin_float fault, only even pins 4 and 8 provide the fault response FR1.

### Further Examples

Example 1 is a fault detection system that includes a pull-up driver circuit having an output coupled to a terminal, a pull-down driver circuit having an output coupled to the terminal, and a comparator circuit configured to compare driver current at the terminal to an expected driver current range, and to output a fault signal associated with the terminal responsive to the driver current being out of range.

Example 2 includes the fault detection system of Example 1, wherein the pull-up driver circuit is a series voltage regulator and the pull-down driver circuit is a shunt voltage regulator

Example 3 includes the fault detection system of Example 1 or 2, wherein the pull-up driver circuit includes a first transistor coupled to the terminal, and the pull-down driver circuit includes a second transistor coupled to the terminal.

Example 4 includes the fault detection system of any one of Examples 1-3, wherein the comparator circuit is configured to: compare a mirrored current from the pull-up driver circuit and/or the pull-down driver circuit to a reference current; and output the fault signal as either a logic HIGH or logic LOW based on the comparison.

Example 5 includes the fault detection system of any one of Examples 1-4, wherein the terminal is a first terminal and the system further comprises a second terminal adjacent to the first terminal, and wherein the fault signal is indicative of a short-circuit between the first terminal and the second terminal.

Example 6 includes the fault detection system of Example 5, wherein the comparator circuit is configured to output a logic HIGH or logic LOW based on a comparison between a first current on the first terminal during a first time period and a second current on the first terminal during a second adjacent time period, wherein a voltage applied to one or more driver circuits coupled to the second terminal changes between the first time period and the adjacent second time period.

Example 7 includes the fault detection system of any one of Examples 1-6, wherein: the pull-up driver circuit includes a first operational amplifier and a first voltage source coupled to a positive input terminal of the first operational amplifier; and the pull-down driver circuit includes a second operational amplifier and a second voltage source coupled to a negative input terminal of the second operational amplifier.

Example 8 includes the fault detection system of Example 7, wherein a negative input terminal of the first operational amplifier is coupled to the terminal, and a positive input terminal of the second operational amplifier is coupled to the terminal.

Example 9 includes the fault detection system of Example 7 or 8, further comprising a controller coupled to the first voltage source and the second voltage source and configured to set a first voltage value for the first voltage source and a second voltage value for the second voltage source.

Example 10 includes the fault detection system of Example 9, wherein the controller comprises a state machine configured to change the first voltage value and second voltage value based on a given time period.

Example 11 includes the fault detection system of Example 9 or 10, wherein the controller is configured to set a first voltage value for the first voltage source and a second voltage value for the second voltage source, the second voltage value being greater than the first voltage value.

Example 12 includes the fault detection system of Example 11, wherein the controller is configured to set the first and second voltage values over a first time period and set different voltage values for the first voltage source and second voltage source over a second time period adjacent to the first time period.

Example 13 includes the fault detection system of Example 12, wherein the controller is configured to adjust the relative lengths of time of the first time period compared to the second time period.

Example 14 includes the fault detection system of any one of Examples 9-13, wherein the controller is configured to decrease the voltage value for the second voltage source and determine a capacitance value for the terminal based on a rate at which a current decreases on the terminal.

Example 15 includes the fault detection system of Example 14, wherein the comparator circuit is further configured to output the fault signal being indicative of a floating state of the terminal based at least partially on the capacitance value of the terminal being lower than a threshold value.

Example 16 includes the fault detection system of any one of Examples 1-15, further comprising: a fault response block configured to receive the fault signal and determine a fault response based on the fault signal.

Example 17 includes the fault detection system of Example 16, wherein the fault response block comprises a latch-circuit configured to store at least one value of the received fault signal.

Example 18 includes the fault detection system of Example 16 or 17, wherein the fault response block comprises a switch associated with the terminal for the fault signal.

Example 19 includes the fault detection system of any one of Examples 16-18, wherein the fault response block comprises a first array of switches each associated with a corresponding terminal of a set of terminals for a first received fault signal, and a second array of switches each associated with the corresponding terminal of the set of terminals for a second received fault signal.

Example 20 includes the fault detection system of any one of Examples 1-19, wherein the comparator circuit is one of a plurality of comparator circuits, each of the comparator circuits configured to receive a mirrored current from the pull-up driver circuit and/or the pull-down driver circuit, and wherein each of the comparator circuits is configured to output a different fault signal associated with a different type of fault.

Example 21 includes the fault detection system of Example 20, wherein the different type of fault includes any one of a grounded terminal fault, a floating terminal fault, a shorted to a supply terminal fault, or a shorted to an adjacent terminal fault.

Example 22 is an integrated circuit package, comprising the fault detection system of any one of Examples 1-21, wherein the terminal is an input and/or output terminal of the integrated circuit package.

Example 23 is an integrated circuit that includes an integrated circuit package having a terminal and a fault detector circuit within the integrated circuit package and coupled to the terminal. The fault detector circuit is configured to output at least one fault signal associated with the terminal and includes a first voltage regulator coupled to the terminal, a second voltage regulator coupled to the terminal, and a fault comparison block configured to receive a mirrored current from the first voltage regulator and/or the second voltage regulator. The fault comparison block is configured to output a fault signal of the at least one fault signal.

Example 24 includes the integrated circuit of Example 23, wherein the first voltage regulator is a series voltage regulator, and the second voltage regulator is a shunt voltage regulator.

Example 25 includes the integrated circuit of Example 23 or 24, wherein the first voltage regulator includes a first metal oxide semiconductor field effect transistor (MOSFET) at its output and having a source terminal directly coupled to the terminal, and the second voltage regulator includes a second MOSFET at its output and having a drain terminal directly coupled to the terminal.

Example 26 includes the integrated circuit of any one of Examples 23-25, wherein the fault detector circuit comprises a plurality of fault comparison blocks, each of the fault comparison blocks configured to receive a mirrored current from the first voltage regulator and/or the second voltage regulator, and wherein each of the fault comparison blocks is configured to output a different fault signal associated with a different type of fault.

Example 27 includes the integrated circuit of Example 26, wherein the different type of fault includes any one of a grounded pin fault, a floating pin fault, a shorted pin fault to a supply, or a shorted pin fault to an adjacent pin.

Example 28 includes the integrated circuit of Example 26 or 27, wherein at least one of the fault comparison blocks is configured to compare the received mirrored current to a reference current and output the corresponding fault signal as either a logic HIGH or logic LOW based on the comparison.

Example 29 includes the integrated circuit of any one of Examples 23-28, wherein the terminal is a first terminal and the integrated circuit package further comprises a second terminal adjacent to the first terminal, and wherein the at least one fault signal includes a pin short fault signal indicative of a short-circuit between the first terminal and the second terminal.

Example 30 includes the integrated circuit of Example 29, wherein the fault comparison block is configured to output the pin short fault signal indicative of a short-circuit between the first terminal and the second terminal as either a logic HIGH or logic LOW based on a comparison between a first current on the first terminal during a first time period and a second current on the first terminal during a second adjacent time period, wherein a voltage applied to one or more driver circuits coupled to the second terminal changes between the first time period and the adjacent second time period.

Example 31 includes the integrated circuit of any one of Examples 23-30, wherein: the first voltage regulator includes a first operational amplifier and a first voltage source coupled to a positive input terminal of the first operational amplifier; and the second voltage regulator includes a second operational amplifier and a second voltage source coupled to a negative input terminal of the second operational amplifier.

Example 32 includes the integrated circuit of Example 31, wherein a negative input terminal of the first operational amplifier is directly coupled to the terminal and a positive input terminal of the second operational amplifier is directly coupled to the terminal.

Example 33 includes the integrated circuit of Example 31 or 32, further comprising a controller coupled to the first voltage source and the second voltage source and configured to set a first voltage value for the first voltage source and a second voltage value for the second voltage source.

Example 34 includes the integrated circuit of Example 33, wherein the controller comprises a state machine configured to change the first voltage value and second voltage value based on a given time period.

Example 35 includes the integrated circuit of any one of Examples 23-34, further comprising: a fault response block configured to receive the at least one fault signal and determine a fault response based on the at least one fault signal.

Example 36 includes the integrated circuit of Example 35, wherein the fault response block comprises a memory configured to store at least one value of the received at least one fault signal.

Example 37 includes the integrated circuit of Example 35 or 36, wherein the fault response block comprises a latch configured to store at least one value of the received at least one fault signal.

Example 38 includes the integrated circuit of any one of Examples 35-37, wherein the fault response block comprises a switch associated with the terminal for each received at least one fault signal.

Example 39 includes the integrated circuit of any one of Examples 35-38, wherein the fault response block comprises a first array of switches each associated with a corresponding terminal of a set of terminal of the integrated circuit package for a first received fault signal, and a second array of switches each associated with the corresponding terminal of the set of terminals for a second received fault signal.

Example 40 is an integrated circuit that includes a plurality of pins, a multiplexer having inputs coupled to corresponding pins of the plurality of pins, and a pin fault detector having a pin input coupled to an output of the multiplexer and configured to output at least one fault signal associated with one pin of the plurality of pins as selected by the multiplexer. The pin fault detector includes a first voltage regulator coupled to the pin input, a second voltage regulator coupled to the pin input, and at least one fault comparison block configured to receive a mirrored current from the first voltage regulator and/or the second voltage regulator. Each of the one or more fault comparison blocks is configured to output a corresponding fault signal of the at least one fault signal.

Example 41 includes the integrated circuit of Example 40, wherein the plurality of pins is a first plurality of pins, the multiplexer is a first multiplexer, the pin fault detector is a first pin fault detector, and the integrated circuit further includes a second plurality of pins, a second multiplexer having inputs coupled to corresponding pins of the second plurality of pins, and a second pin fault detector having a pin input coupled to an output of the second multiplexer and configured to output at least one fault signal associated with one pin of the plurality of second pins as selected by the second multiplexer.

Example 42 includes the integrated circuit of Example 41, wherein each pin of the first plurality of pins is adjacent only to pins of the second plurality of pins.

Example 43 includes the integrated circuit of any one of Examples 40-42, wherein the first voltage regulator is a series voltage regulator and the second voltage regulator is a shunt voltage regulator.

Example 44 includes the integrated circuit of any one of Examples 40-43, wherein the first voltage regulator includes a first field effect transistor (FET) at its output and having a source terminal directly coupled to the pin input, and the second voltage regulator includes a second FET at its output and having a drain terminal directly coupled to the pin input.

Example 45 includes the integrated circuit of any one of Examples 40-44, wherein the integrated circuit includes a plurality of fault comparison blocks, each of the fault comparison blocks configured to receive a mirrored current from the first voltage regulator and/or the second voltage regulator, and wherein each of the fault comparison blocks is configured to output a different fault signal associated with a different type of fault.

Example 46 includes the integrated circuit of Example 45, wherein the different type of fault includes any one of a grounded pin fault, a floating pin fault, a shorted to a supply pin fault, or a shorted to an adjacent pin fault.

Example 47 includes the integrated circuit of any one of Examples 40-46, wherein the at least one fault comparison block is configured to: compare the received mirrored current to a reference current; and output the fault signal as either a logic HIGH or logic LOW based on the comparison.

Example 48 includes the integrated circuit of any one of Examples 40-47, wherein: the first voltage regulator includes a first operational amplifier and a first voltage source coupled to a positive input terminal of the first operational amplifier; and the second voltage regulator includes a second operational amplifier and a second voltage source coupled to a negative input terminal of the second operational amplifier.

Example 49 includes the integrated circuit of Example 48, wherein a negative input terminal of the first operational amplifier is coupled to the pin input and a positive input terminal of the second operational amplifier is coupled to the pin input.

Example 50 includes the integrated circuit of Example 48 or 49, further comprising a controller coupled to the first voltage source and the second voltage source and configured to set a first voltage value for the first voltage source and a second voltage value for the second voltage source.

Example 51 includes the integrated circuit of Example 50, wherein the controller comprises a state machine configured to change the first voltage value and second voltage value based on a given time period.

Example 52 includes the integrated circuit of any one of Examples 40-51, further comprising a fault response block configured to receive the at least one fault signal and determine a fault response based on the at least one fault signal.

Example 53 includes the integrated circuit of Example 52, wherein the fault response block comprises a memory configured to store at least one value of the at least one fault signal.

Example 54 includes the integrated circuit of Example 53, wherein the memory comprises a latch.

Example 55 includes the integrated circuit of any one of Examples 52-54, wherein the fault response block comprises a switch associated with the one pin.

Example 56 includes the integrated circuit of any one of Examples 52-55, wherein the fault response block comprises: a first array of switches each associated with a corresponding pin of the plurality of pins for a first received fault signal; and a second array of switches each associated with the corresponding pin of the plurality of pins for a second received fault signal.

Example 57 includes the fault detection system of Example 1, the integrated circuit of Example 23, or the integrated circuit of Example 40, further comprising a controller configured to control at least one voltage applied to the pull-up driver circuit, the pull-down driver circuit, the first voltage regulator, or the second voltage regulator.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pad,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end user and/or a third party.

While the use of particular transistors is described herein, other transistors (or equivalent devices) may be used instead. For example, a p-channel field effect transistor (PFET) may be used in place of an n-channel field effect transistor (NFET) with little or no changes to the circuit. Furthermore, other types of transistors may be used (such as bipolar junction transistors (BJTs)). Furthermore, the devices may be implemented in/over a silicon substrate (Si), a silicon carbide substrate (SiC), a gallium nitride substrate (GaN) or a gallium arsenide substrate (GaAs). Moreover, reference to transistor features such as gate, source, or drain is not intended to exclude any suitable transistor technologies. For instance, features such as source, drain, and gate are typically used to refer to a FET, while emitter, collector, and base are typically used to refer to a BJT. Such features may be used interchangeably herein. For instance, reference to the gate of a transistor may refer to either the gate of a FET or the base of a BJT, and vice-versa. In some examples, a control terminal may refer to either the gate of a FET or the base of a BJT. Any other suitable transistor technologies can be used. Any such transistors can be used as a switch, with the gate or base or other comparable feature acting as a switch select input that can be driven to connect the source and drain (or the emitter and collector, as the case may be).

References herein to a field effect transistor (FET) being “ON” (or a switch being closed) means that the conduction channel of the FET is present, and drain current may flow through the FET. References herein to a FET being “OFF” (or a switch being open) means that the conduction channel is not present, and drain current does not flow through the FET. A FET that is OFF, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

Modifications are possible in the described examples, and other examples are possible within the scope of the claims.

What is claimed is:

1. A fault detection system, comprising:
a pull-up driver circuit having an output coupled to a terminal;
a pull-down driver circuit having an output coupled to the terminal; and
a comparator circuit configured to compare driver current at the terminal to an expected driver current range, and to output a fault signal associated with the terminal responsive to the driver current being out of the expected driver current range.

2. The system of claim 1, wherein the pull-up driver circuit includes a first transistor coupled to the terminal, and the pull-down driver circuit includes a second transistor coupled to the terminal.

3. The system of claim 1, wherein the comparator circuit is configured to: determine a comparison between a mirrored current from the pull-up driver circuit and/or the pull-down driver circuit and a reference current; and output the fault signal as either a logic HIGH or logic LOW based on the comparison.

4. The system of claim 1, wherein the terminal is a first terminal and the system further comprises a second terminal adjacent to the first terminal, and wherein the fault signal is indicative of a short-circuit between the first terminal and the second terminal.

5. The system of claim 4, wherein the comparator circuit is configured to output a logic HIGH or logic LOW based on a comparison between a first current on the first terminal during a first time period and a second current on the first terminal during a second adjacent time period, wherein a voltage applied to one or more driver circuits coupled to the second terminal changes between the first time period and the adjacent second time period.

6. The system of claim 1, wherein: the pull-up driver circuit includes a first operational amplifier and a first voltage source coupled to a positive input terminal of the first operational amplifier; and the pull-down driver circuit includes a second operational amplifier and a second voltage source coupled to a negative input terminal of the second operational amplifier, wherein a negative input terminal of the first operational amplifier is coupled to the terminal, and a positive input terminal of the second operational amplifier is coupled to the terminal.

7. The system of claim 6, further comprising a controller coupled to the first voltage source and the second voltage source and configured to set a first voltage value for the first voltage source and a second voltage value for the second voltage source.

8. The system of claim 7, wherein the controller is configured to decrease the voltage value for the second voltage source and determine a capacitance value for the terminal based on a rate at which a current decreases on the terminal.

9. The system of claim 1, wherein the comparator circuit is one of a plurality of comparator circuits, each of the comparator circuits configured to receive a mirrored current from the pull-up driver circuit and/or the pull-down driver circuit, and wherein each of the comparator circuits is configured to output a different fault signal associated with a different type of fault.

10. The system of claim 9, wherein the different type of fault includes any one of a grounded terminal fault, a floating terminal fault, a shorted to a supply terminal fault, or a shorted to an adjacent terminal fault.

11. An integrated circuit, comprising:
an integrated circuit package having a terminal; and
a fault detector circuit within the integrated circuit package and coupled to the terminal, the fault detector circuit configured to output at least one fault signal associated with the terminal, wherein the fault detector circuit includes:
a first voltage regulator coupled to the terminal,
a second voltage regulator coupled to the terminal, and
a fault comparison block configured to receive a mirrored current from one of the first voltage regulator and the second voltage regulator, wherein the fault comparison block is configured to output a fault signal of the at least one fault signal.

12. The integrated circuit of claim 11, wherein the first voltage regulator is a series voltage regulator, and the second voltage regulator is a shunt voltage regulator.

13. The integrated circuit of claim 11, wherein the fault detector circuit comprises a plurality of fault comparison blocks, each of the fault comparison blocks configured to receive a mirrored current from the first voltage regulator and/or the second voltage regulator, and wherein each of the fault comparison blocks is configured to output a different fault signal associated with a different type of fault.

14. The integrated circuit of claim 13, wherein at least one of the fault comparison blocks is configured to compare the received mirrored current to a reference current and output the corresponding fault signal as either a logic HIGH or logic LOW based on the comparison.

15. The integrated circuit of claim 11, further comprising: a fault response block configured to receive the at least one fault signal and determine a fault response based on the at least one fault signal.

16. An integrated circuit, comprising:
a plurality of pins;
a multiplexer having inputs coupled to corresponding pins of the plurality of pins; and
a pin fault detector having a pin input coupled to an output of the multiplexer and configured to output at least one fault signal associated with one pin of the plurality of pins as selected by the multiplexer, wherein the pin fault detector includes:
a first voltage regulator coupled to the pin input,
a second voltage regulator coupled to the pin input, and
at least one fault comparison block configured to receive a mirrored current from the first voltage regulator and/or the second voltage regulator, wherein each of the one or more fault comparison blocks is configured to output a corresponding fault signal of the at least one fault signal.

17. The integrated circuit of claim 16, wherein the plurality of pins is a first plurality of pins, the multiplexer is a first multiplexer, and the pin fault detector is a first pin fault detector, the integrated circuit further comprising:
a second plurality of pins;
a second multiplexer having inputs coupled to corresponding pins of the second plurality of pins; and
a second pin fault detector having a pin input coupled to an output of the second multiplexer and configured to output at least one fault signal associated with one pin of the plurality of second pins as selected by the second multiplexer.

18. The integrated circuit of claim 17, wherein each pin of the first plurality of pins is adjacent only to pins of the second plurality of pins.

19. The integrated circuit of claim 16, wherein the integrated circuit includes a plurality of fault comparison blocks, each of the fault comparison blocks configured to receive a mirrored current from the first voltage regulator and/or the second voltage regulator, and wherein each of the fault comparison blocks is configured to output a different fault signal associated with a different type of fault.

20. The integrated circuit of claim 16, further comprising a fault response block configured to receive the at least one fault signal and determine a fault response based on the at least one fault signal.
